(19) United States
(12) Patent Application Publication
(10) Pub. No.: US 2023/0131457 A1
(43) Pub. Date: Apr. 27, 2023

(54) METHOD FOR SIMULATING AN EMBOSSMENT IN MANUFACTURE OF SERVER CASING AND ELECTRONIC DEVICE EMPLOYING METHOD

(71) Applicant: Fulian Precision Electronics (Tianjin) Co.,LTD., Tianjin (CN)

(72) Inventors: KUANG-HUI MA, New Taipei (TW); YU-CHENG CHEN, Taipei (TW)

(21) Appl. No.: 17/548,787

(22) Filed: Dec. 13, 2021

(30) Foreign Application Priority Data
Oct. 22, 2021 (CN) 202111234322.9

(51) Int. Cl. G06F 30/10; G06F 16/2455

(52) U.S. Cl. CPC G06F 30/10; G06F 16/2455

(57) ABSTRACT

A method for fast simulation of possible embossments or pressings of a server casing in manufacture includes obtaining a first design table of design layout scheme; converting machine language for each group of layout schemes in the first design table to import the first design table into a simulation software. Each group of the embossment design layout schemes is simulated to obtain chassis strength or of part of chassis, and each group of the embossment design layout scheme and corresponding chassis strength is stored to the database and identical stored schemes are filtered out. The disclosure also provides an electronic device and a non-transitory storage medium.

### TECHNICAL FIELD

The present disclosure relates to intelligent manufacturing technology, particularly to embossment simulating method and electronic device.

### BACKGROUND

An engineer manually inputs each group of embossment design and equipment scheme into the simulation software (such as LS DYNA) for simulation to determine which group of embossment design and equipment scheme can make the server shell have the maximum bearing strength. The engineers usually can only select a few groups from hundreds or thousands of embossment designs and furnishing schemes for simulation, and then select the best embossment design and furnishing scheme from the simulation results to obtain the corresponding chassis bearing strength and apply it to the factory for the server casing manufacture.

This method manually inputs the embossment design and equipment scheme into the simulation software for simulation, which is quite time-consuming, and the embossment design finally selected and equipment scheme may not be the best design.

Therefore, improvement is desired.

### BRIEF DESCRIPTION OF THE DRAWINGS

FIG. 1 is a schematic diagram of a server chassis according to an embodiment of the present disclosure.

FIG. 2 is a schematic diagram of an embossment according to another embodiment of the present disclosure.

FIG. 3 is a schematic diagram showing strength of chassis under test, according to an embodiment of the present disclosure.

FIG. 4 is a schematic diagram of an electronic device according to an embodiment of the present disclosure.

FIG. 5 is a flowchart of an embossment simulating method according to an embodiment of the present disclosure.

FIG. 6 is a flowchart of an embossment simulating method according to another embodiment of the present disclosure.

FIG. 7 is a flowchart of an embossment simulating method according to another embodiment of the present disclosure.

### DETAILED DESCRIPTION

The technical solutions in the embodiments of the present disclosure will be described in conjunction with the accompanying drawings in the embodiments of the present disclosure. Obviously, the described embodiments are part of the embodiments of the present disclosure, not all of them. Based on the embodiments of the present disclosure, all other embodiments obtained by those of ordinary skill in the art without creative work shall fall within the protection scope of the present disclosure.

It should be noted that “at least one” in the embodiment of the present disclosure refers to one or more, and multiple refers to two or more. For example, the terms “first”, “second”, “third”, “fourth” in the description, claims and drawings of the application are used to distinguish similar objects, rather than to describe a specific order.

When designing a chassis of a server, design engineer inputs the embossment design and equipment scheme into a simulation software program, to determine which group of the embossment design and equipment scheme can make the chassis of the server have the maximum strength.

Take LS DYNA simulation software as an example. The LS DYNA simulation software includes a HyperMesh module, a manager module, and a LS Prepost module. The HyperMesh module is used to establish the shape of the embossment according to a first parameter and a second parameter of the embossment, and output a K file. The first parameter of embossment is integrated into an HM file, and the design engineer can import the HM file into the HyperMesh module. The first parameter of the embossment may include the shape and thickness of the chassis, as well as the weight distribution (such as middle, front, or rear of the chassis).

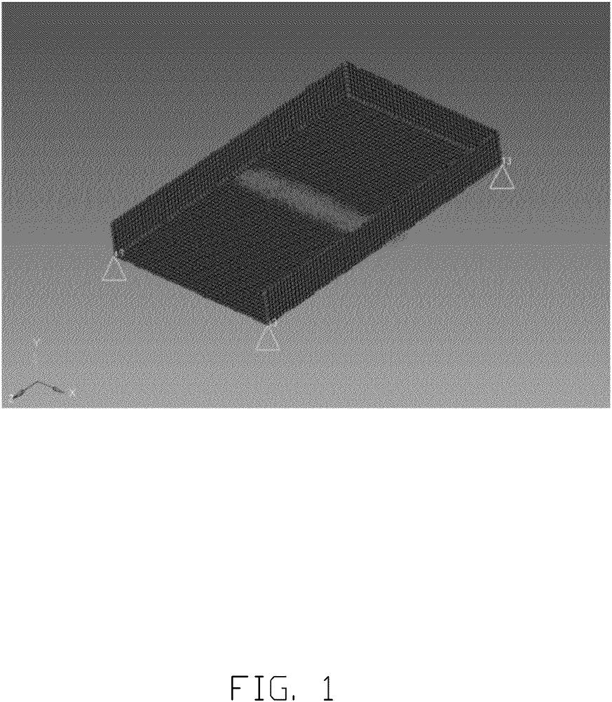

Referring to FIG. 1, the HyperMesh module can establish the shape of the final casing according to the first parameter of the embossment. The design engineer can change the shape of the chassis by adjusting the first parameter of the embossment in the HM file. The second parameter of the embossment needs to be manually input to the HyperMesh module by the design engineer. The second parameter of the embossment may include the height and width of the embossment, the number of embossments, and the distance between embossments.

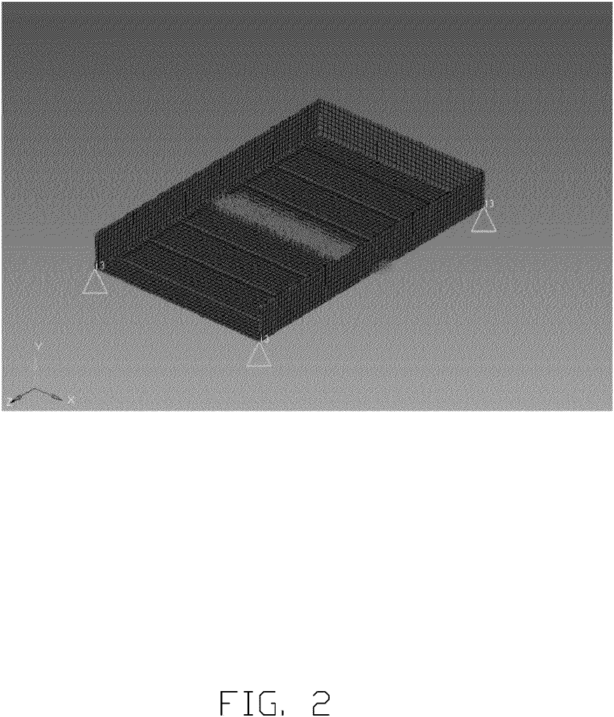

Referring to FIG. 2, the HyperMesh module can establish the shape of the embossment according to the first parameter and the second parameter of the embossment. The design engineer can change the shape of the embossment by adjusting the second parameter of the embossment.

The design engineers can import K file into the manager module. The manager module is used to simulate the chassis strength according to the shape of the embossment. The manager module can read the outline of the embossment from the K file, perform simulation operations, and output a D3plot file. The D3plot file is in the same folder as the K file.

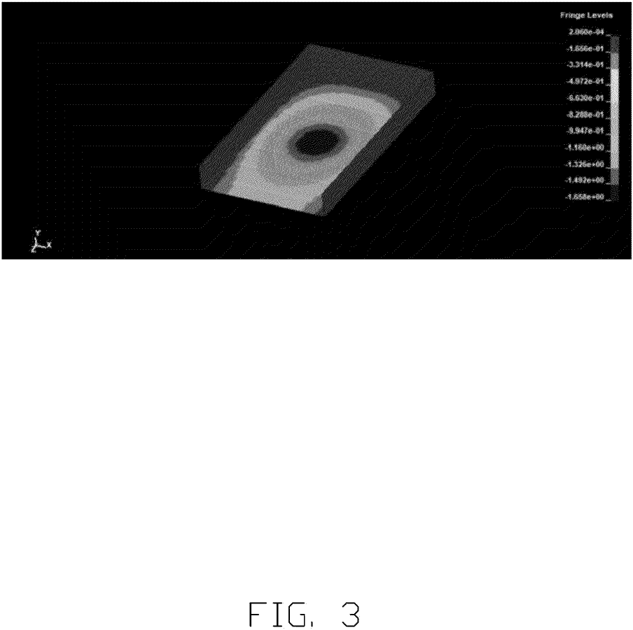

The design engineers can import the D3plot file into the LS Prepost module. The Ls Prepost module is used to read the D3plot file and display displacement diagram. Referring to FIG. 3, the displacement diagram is used to show the chassis strength corresponding to the embossment.

The design engineer manually inputs the embossment design scheme into the simulation software for simulation. The average simulation time of a group of the embossment design schemes is about 0.5 h. As shown in Table 1, when the combination of parameters of the embossment can form 2420 groups of the embossment design layout schemes, the simulation time will reach 1210h, which greatly affects the work efficiency of design engineers.

TABLE 1

parameter setting of the embossment

| weight distribution | thickness of the chassis (mm) | height of the embossment (mm) | number of the embossments | width of the embossment (mm) | first distance between the embossments (mm) | second distance between the embossments (mm) |
|---|---|---|---|---|---|---|
| middle | 1 | 1 | 4 | 60 | 20 | 20 |
| / | 1.2 | 1.5 | / | 80 | 40 | 40 |
| / | / | 2 | / | / | 60 | 60 |
| / | / | 2.5 | / | / | 80 | 80 |
| / | / | 3 | / | / | 100 | 100 |
| / | / | / | / | / | 120 | 120 |
| / | / | / | / | / | 160 | 160 |
| / | / | / | / | / | 200 | 200 |
| / | / | / | / | / | 240 | 240 |
| / | / | / | / | / | 280 | 280 |
| / | / | / | / | / | 320 | 320 |

The embodiment of the present disclosure provides a embossment simulating method, an electronic device, and a storage medium, which can improve the simulation software, effectively reduce the simulation time of the simulation software, and improve the work efficiency of the design engineer.

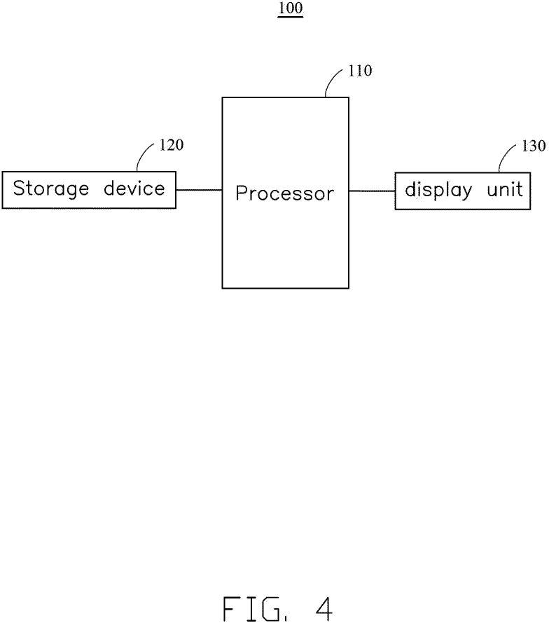

FIG. 4 illustrates an electronic device 100 in accordance with an embodiment of the present disclosure.

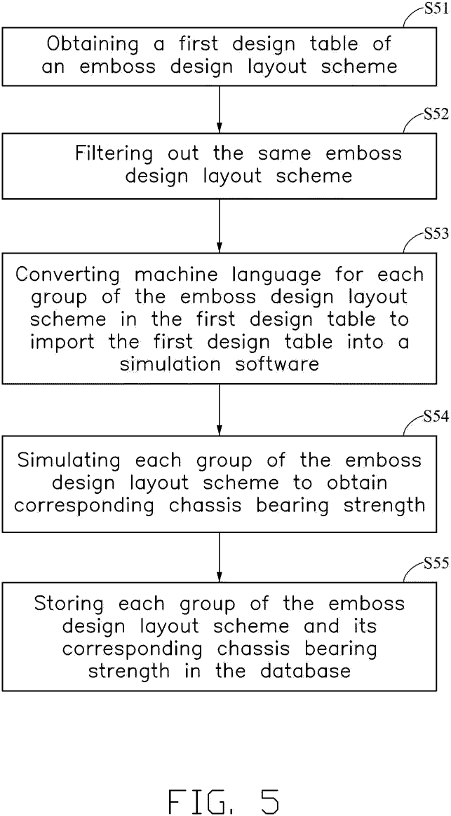

The electronic device 100 may include, but is not limited to, a storage device 120, a processor 110, and a display unit 130. The processor 110 may execute the program code or the program segment of the storage device 120 to implement the embossment simulating method shown in FIGS. 5-7.

The block diagram merely shows an example of the electronic device 100 and does not constitute a limitation to the electronic device 100. In other examples, more or less components than those illustrated may be included, or some components may be combined, or different components used. For example, the electronic device 100 may also include input and output devices, a network access devices, a bus, and the like.

The processor 110 may include one or more central processing units (CPUs). For example, the processor 110 may include a general purpose processor, a digital signal processor (DSP), an application specific integrated circuit (ASIC), a Field-Programmable gate array (FPGA) or other programmable logic device, a transistor logic device, a discrete hardware component, a neural-network processing unit (NPU), and a baseband processor. The general purpose processor may be a microprocessor. The processor 110 is a control center of the electronic device 100. The processor 110 connects the parts of the electronic device 100 by using various interfaces and lines. A memory may also be provided in the processor 110 for storing instructions and data. In some embodiments, the memory in the processor 110 is a cache memory. The memory may store instructions or data just used or recycled by the processor 110. If the processor 110 needs to use the instruction or data again, it can be called up directly from the memory.

In one embodiment, the processor 110 may include one or more interfaces. the interfaces may include, but are not limited to, an integrated circuit (I2C) interface, an integrated circuit sound (I2S) interface, a pulse code modulation (PCM) interface, a universal asynchronous receiver/transmitter (UART) interface, a mobile industry processor interface mobile industry processor interface (MIPI), a general purpose input output (GPIO) interface, a subscriber identity module (SIM) interface, and a universal serial bus (USB) interface.

The interface connection relationship between the modules illustrated in the embodiment of the present disclosure is only a schematic description and does not constitute a structural limitation of the electronic device 100. In other embodiments of the present disclosure, the electronic device 100 may also adopt different interface connection modes or a combination of multiple interface connection modes in the above embodiments.

The storage device 120 may include an external memory interface and an internal memory. The external memory interface can be used to connect an external memory card, such as a micro SD card, to expand the storage capacity of the electronic device 100. The external memory card communicates with the processor 110 through the external memory interface to realize the data storage function. The internal memory may be used to store computer executable program code, which includes instructions. The internal memory may include a storage program area and a storage data area. The storage program area can store the operating system, application programs required for at least one function (such as sound playback function, image playback function). The storage data area may store data (such as audio data, phonebook, etc.) created during the use of the electronic device 100. The internal memory may include random-access memory and nonvolatile memory, such as at least one disk storage device, flash memory device, and universal flash storage (UFS). The processor 110 executes various functional applications and data processing of the electronic device 100 by running instructions stored in the internal memory and/or instructions stored in the storage device provided in the processor 110, so as to realize the embossment simulating method of the embodiment of the present disclosure.

The display unit 130 includes a display panel. The display panel can be, but is not limited to, liquid crystal display (LCD), organic light emitting diode (OLED), active-matrix organic light emitting diode or active-matrix organic light emitting diode (AMOLED), flexible light emitting diode (FLED), mini LED micro LED, micro OLED, quantum dot light emitting diode (QLED). In some embodiments, the electronic device 100 may include one or up to ND display units 130, ND being a positive integer greater than 1.

The structure illustrated in the embodiment of the present disclosure does not constitute a specific limitation on the electronic device 100. In other embodiments of the present disclosure, the electronic device 100 may include more or fewer components than shown, or combine some components, or split some components, or different component arrangements. The illustrated components may be implemented in hardware, software, or a combination of software and hardware.

FIG. 5 is a flowchart depicting an embodiment of an embossment simulating method.

In one embodiment, the embossment simulating method can be applied to the electronic device 100 (shown in FIG. 4). For an electronic device to simulate embossment, the function for simulating embossment provided by the method of the present disclosure can be directly integrated on the electronic device 100, or can be run on the electronic device 100 in the form of a software development kit (SDK).

Each block shown in FIG. 5 represents one or more processes, methods, or subroutines, carried out in the example method. Furthermore, the illustrated order of blocks is illustrative only and the order of the blocks can change. Additional blocks can be added or fewer blocks may be utilized, without departing from the present disclosure. The example method can begin at block 51.

At block 51, obtaining a first design table of an embossment design layout scheme.

In the embodiment, the first design table is used to record the parameters of embossment. The first design table may include parameters such as the opening form and thickness of the chassis, the height and width of the embossment, the number of the embossment, and the distance between the embossments. The opened form of the chassis can include full opened or half opened. In one embodiment, the thickness of the chassis may be 1 mm or 1.2 mm. The height of the embossment can be 1-3 mm. The width of the embossment can be 20-500 mm. The number of the embossment can be 1-25. The distance between the embossment can be 20-500 mm.

For example, there are NE design engineers in the chassis design department, and NE is a positive integer. Each design engineer can record the embossment design and equipment scheme considered to be developed on the server chassis in the first design table. The chassis design department has NE first design tables in total, of which each design engineer has a corresponding first design table. The design engineer can change the embossment design layout scheme by adjusting the parameters of the embossment in the first design table.

In one embodiment, the embossment design layout scheme in a first design table can be one or more groups.

In another embodiment, multiple groups of the embossment design layout schemes in the first design table can be aggregated into multiple files (such as K file), and a group of the embossment design layout schemes correspond to a file.

In another embodiment, the first design table can be in the form of Notepad or spreadsheet (Excel).

At block 52, filtering out embossment design layout schemes which are the same.

In the embodiment, the embossment design layout scheme in the first design table can be summarized to filter out identical embossment design layout schemes, so as to save storage space.

At block 53, converting machine language for each group of the embossment design layout scheme in the first design table to import the first design table into a simulation software.

In the embodiment, simulation software (such as LS DYNA) is installed on the electronic device 100. The machine language conversion can be performed for each group of the embossment design layout scheme in the first design table, the text format of the embossment design layout scheme can be converted into a machine language format (such as Python) recognized by the simulation software, and one or more corresponding files (such as K files) can be exported. Then import one or more files into the simulation software.

At block 54, simulating each group of the embossment design layout scheme to obtain corresponding chassis strength.

In the embodiment, the simulation software can simulate the embossment design layout scheme, and can output a corresponding chassis strength. Each group of the embossment design layout scheme corresponds to the strength of a chassis or part of a chassis.

At block 55, storing each group of the embossment design layout scheme and its corresponding chassis strength in the database.

In the embodiment, the electronic device 100 is communicatively connected to the database. The database can be established on a local server or a cloud server.

In some embodiments, each group of the embossment design layout schemes and its corresponding chassis strength can be stored in the database in the form of key value pairs. By querying the parameters of the embossment design layout scheme, the group of the embossment design layout schemes in the database and their corresponding chassis strengths can be obtained.

In the embodiment, the improved simulation software can automatically simulate the embossment design layout scheme in machine language to obtain the corresponding chassis strength. It is not necessary for the design engineer to manually input the embossment parameters, nor to import and export multiple files. It can batch simulate the embossment design layout scheme, greatly reducing the development time and labor cost. The simulation software can continuously simulate the embossment design layout scheme, which greatly enriches the data samples and provides a more comprehensive data reference for the scheme selection of the design engineers.

Take LS DYNA simulation software as an example. The embodiment improves the LS DYNA simulation software and simplifies the workflow of the HyperMesh module, the manager module, and the LS Prepost module into one-step import and one-step output.

The design engineer imports the first design table into LS DYNA simulation software. The LS DYNA simulation software can automatically modify and export a K file, read the embossment shape from the K file, carry out simulation operation, output a D3plot file, then read the D3plot file and display the displacement diagram.

In the embodiment, the embossment design layout scheme is input to LS DYNA simulation software for simulation. The average simulation time of a group of the embossment design layout schemes is about 31 s. Referring to Table 1, when the parameter combinations of the embossment can form 2420 groups of the embossment design layout schemes, the simulation time is about 20.8 h. Compared with the manual mode, about 1189.2 h of simulation time can be saved. The embodiment of the present disclosure can greatly reduce the simulation time and improve the work efficiency of the design engineer.

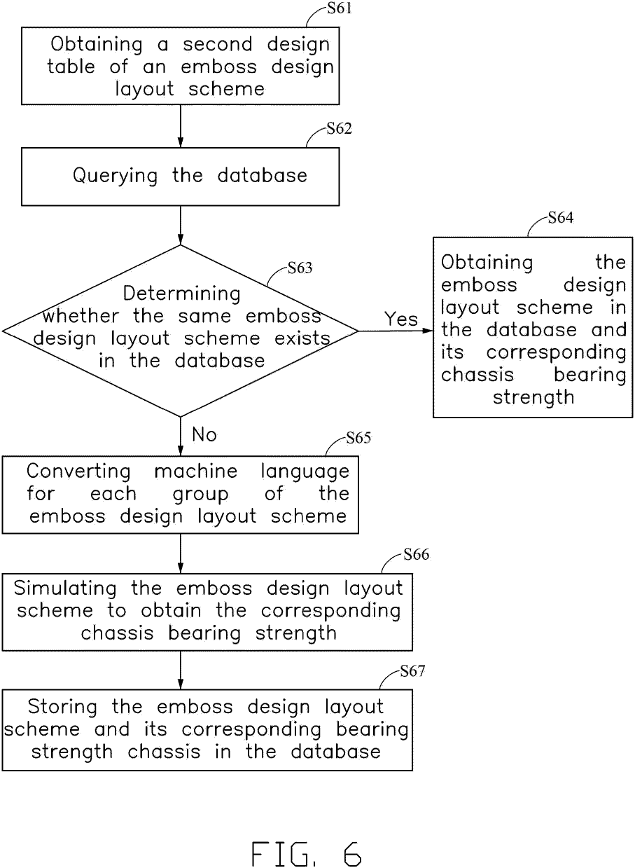

FIG. 6 is a flowchart depicting another embodiment of a embossment simulating method. The example method can begin at block 61.

At block 61, obtaining a second design table of a embossment design layout scheme.

In some embodiments, the design engineer can list hundreds or thousands of groups of the embossment design layout schemes on the server chassis when designing and developing the server chassis products, and record these embossment design layout schemes in the second design table. In the embodiment, the first design table may include parameters such as the opened form and thickness of the chassis, the height and width of the embossment, the number of the embossment, and the distance between the embossments.

At block 62, querying database.

In the embodiment, the database stores all the design engineers of the chassis design department who have considered the embossment design layout scheme developed on the server chassis.

In some embodiments, by querying the parameters of the embossment design layout scheme, the group of the embossment design layout schemes and the corresponding chassis strength in the database can be obtained.

At block 63, determining whether embossment design layout schemes exists in the database which are the same. If the same embossment design layout scheme exists in the database, the block 64 is implemented, otherwise the block 65 is implemented.

In the embodiment, the parameters of a group of the embossment design layout scheme correspond to the strength of a chassis. If the parameters of the two groups of the embossment design layout schemes are the same, it means that the two groups of the embossment design layout schemes are the same.

At block 64, obtaining the embossment design layout scheme in the database and its corresponding chassis strength.

In the embodiment, the parameters of the embossment design layout scheme are queried. If identical, or virtually identical, embossment design layout schemes are stored in the database, the query is completed, and the design engineer does not need to simulate the embossment design layout scheme, but can directly obtain the embossment design layout scheme in the database and its corresponding chassis strength, so as to save simulation time.

At block 65, converting machine language of each group of the embossment design layout schemes.

In the embodiment, the parameters of the embossment design layout scheme are queried. If identical embossment design layout schemes are not stored in the database, it indicates that the embossment design layout scheme is a new design, and the machine language conversion of the embossment design layout scheme is required to import the embossment design layout scheme into the simulation software (such as LS DYNA).

In some embodiments, the embossment design layout schemes in the second design table may be aggregated into one or more files (such as K file), and a group of the embossment design layout schemes correspond to a file.

At block 66, simulating the embossment design layout scheme to obtain the corresponding chassis strength.

In the embodiment, the simulation software can simulate the embossment design layout scheme and output the corresponding chassis strength.

At block 67, storing the embossment design layout scheme and its corresponding strength chassis in the database.

In some embodiments, the embossment design layout scheme and its corresponding chassis strength can be stored in the database in the form of key value pairs to expand the data samples in the database.

In the embodiment, when designing and developing the chassis products of the server, the design engineer can first input the parameters of the considered embossment design layout scheme into the database for comparison. If identical embossment design layout scheme is stored in the database, the design engineer can directly obtain the chassis strength corresponding to the embossment design layout scheme without repeated simulation, and the simulation time and the development cost can be saved. If an identical embossment design layout scheme is not stored in the database, the design engineer can simulate the embossment design layout scheme and store the embossment design layout scheme and its corresponding chassis strength in the database to add to and enrich the data samples in the database.

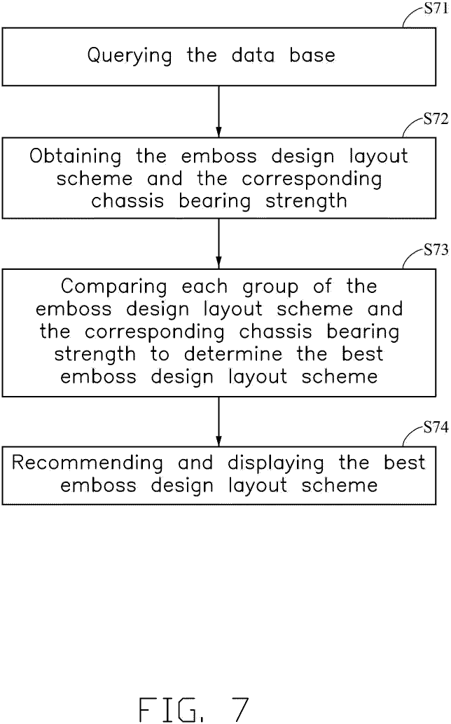

FIG. 7 is a flowchart depicting another embodiment of a embossment simulating method. The example method can begin at block 71.

At block 71, querying data base.

In the embodiment, the database stores all the design engineers of the chassis design department who have considered the embossment design layout scheme developed on the server chassis.

At block 72, obtaining the embossment design layout scheme and its corresponding chassis strength.

In some embodiments, by querying the parameters of one or more groups of the embossment design layout schemes, one or more groups of the embossment design layout schemes and their corresponding chassis strength in the database can be obtained. The parameters of a group of the embossment design layout scheme correspond to the bearing strength of a chassis.

At block 73, comparing each group of the embossment design layout scheme and its corresponding chassis strength to determine the best embossment design layout scheme.

In the embodiment, by comparing each group of embossment design layout schemes and their corresponding strength of chassis, the best embossment design layout scheme required by the current product design and development can be selected. The best embossment design layout scheme corresponds to the largest value of chassis strength.

At block 74, recommending and displaying the best embossment design layout scheme.

In some embodiments, a best embossment design layout scheme may be recommended and displayed on the display unit 130 of the electronic device 100.

In this embodiment, the design engineer can query the stored embossment design layout scheme in the database to obtain all embossment design layout schemes and their corresponding chassis strength indicators that meet the requirements of the current product design and development. The electronic device 100 can determine the best embossment design layout scheme by comparing each group of the embossment design layout schemes and their corresponding chassis strength, and recommend it to the design engineer, so as to improve the production efficiency of the server chassis design department.

The embodiment of the present disclosure also provides a storage medium for storing a computer program or code. When the computer program or code is executed by the processor 110, the embossment simulating method of the embodiment of the present disclosure is realized.

The storage medium can include volatile and non-volatile, removable and non-removable, media implemented in any method or technology for storing information, such as computer-readable instructions, data structures, program modules or other data. Storage media include, but are not limited to, random access memory (RAM), read only memory (ROM), electrically erasable programmable read only memory (EEPROM), flash memory or other memory, compact disc read only memory (CD-ROM), and digital general-purpose optical disc or other optical disk storage, magnetic cartridge, magnetic tape, magnetic disk storage or other magnetic storage device, or any other medium that can be used to store information and can be accessed by a computer.

Those of ordinary skill in the art should realize that the above embodiments are only used to illustrate the present disclosure, but not to limit the present disclosure. As long as they are within the essential spirit of the present disclosure, the above embodiments are appropriately made and changes fall within the scope of protection of the present disclosure.

What is claimed is:

1. An embossment simulating method comprising:
obtaining a first design table of an embossment design layout scheme;
converting machine language for each group of the embossment design layout scheme in the first design table to import the first design table into a simulation software;
simulating each group of the embossment design layout scheme to obtain chassis bearing strength; and
storing each group of the embossment design layout scheme and corresponding chassis bearing strength to the database.

2. The embossment simulating method of claim 1, further comprising:
filtering out the same embossment design layout scheme after the first design table of the embossment design layout scheme is obtained.

3. The embossment simulating method of claim 1, further comprising:
integrating one or more embossment design layout schemes in the first design table into one file; and
importing the file into the simulation software.

4. The embossment simulating method of claim 2, further comprising:
obtaining a second design table of the embossment design layout scheme;
querying the database and determining whether same embossment design layout scheme exists in the database.

5. The embossment simulating method of claim 4, further comprising:
obtaining the embossment design layout scheme in the database and the corresponding chassis bearing strength when the same embossment design layout scheme is exist between the database and the second design table.

6. The embossment simulating method of claim 4, further comprising:
converting machine language for each group of the embossment design layout scheme and importing the second design table into the simulation software when the same embossment design layout scheme does not exist between the database and the second design table;
simulating each group of the embossment design layout scheme to obtain chassis bearing strength; and
storing each group of the embossment design layout scheme and corresponding chassis bearing strength to the database.

7. The embossment simulating method of claim 2, further comprising:
querying the database and obtaining the embossment design layout scheme and corresponding chassis bearing strength;
comparing each group of the embossment design layout scheme and the corresponding chassis bearing strength to determine the best embossment design layout scheme.

8. The embossment simulating method of claim 7, further comprising:
recommending and displaying the best embossment design layout scheme.

9. An electronic device, comprising:
a storage device; and
at least one processor, wherein the storage device stores one or more programs, when executed by the at least one processor, the one or more programs cause the at least one processor to:
obtain a first design table of an embossment design layout scheme;
convert machine language for each group of the embossment design layout scheme in the first design table to import the first design table into a simulation software;
simulate each group of the embossment design layout scheme to obtain chassis bearing strength; and
store each group of the embossment design layout scheme and corresponding chassis bearing strength to the database to the standard format image and the frame size of the standard format pneumonia area.

10. The electronic device according to claim 9, wherein the at least one processor is further caused to:
filter out the same embossment design layout scheme after the first design table of the embossment design layout scheme is obtained.

11. The electronic device according to claim 9, wherein the at least one processor is further caused to:
integrate one or more embossment design layout schemes in the first design table into one file; and
import the file into the simulation software.

12. The electronic device according to claim 10, wherein the at least one processor is further caused to:
obtain a second design table of the embossment design layout scheme;
query the database and determine whether same embossment design layout scheme exists in the database.

13. The electronic device according to claim 12, wherein the at least one processor is further caused to:
obtain the embossment design layout scheme in the database and the corresponding chassis bearing strength when the same embossment design layout scheme is exist between the database and the second design table.

14. The electronic device according to claim 12, wherein the at least one processor is further caused to:
convert machine language for each group of the embossment design layout scheme and import the second design table into the simulation software when the same embossment design layout scheme does not exist between the database and the second design table;
simulate each group of the embossment design layout scheme to obtain chassis bearing strength; and
store each group of the embossment design layout scheme and corresponding chassis bearing strength to the database.

15. The electronic device according to claim 10, wherein the at least one processor is further caused to:
query the database and obtain the embossment design layout scheme and corresponding chassis bearing strength;
compare each group of the embossment design layout scheme and the corresponding chassis bearing strength to determine the best embossment design layout scheme.

16. A non-transitory storage medium having stored thereon instructions that, when executed by a processor of an electronic device, causes the processor to perform an embossment simulating method, the method comprising:
obtaining a first design table of an embossment design layout scheme;
converting machine language for each group of the embossment design layout scheme in the first design table to import the first design table into a simulation software;
simulating each group of the embossment design layout scheme to obtain chassis bearing strength; and
storing each group of the embossment design layout scheme and corresponding chassis bearing strength to the database.

17. The non-transitory storage medium of claim 16, further comprising:
filtering out the same embossment design layout scheme after the first design table of the embossment design layout scheme is obtained.

18. The non-transitory storage medium of claim 16, further comprising:
integrating one or more embossment design layout schemes in the first design table into one file; and
importing the file into the simulation software.

19. The non-transitory storage medium of claim 17, further comprising:
obtaining a second design table of the embossment design layout scheme;
querying the database and determining whether same embossment design layout scheme exists in the database.

20. The non-transitory storage medium of claim 19, further comprising:
obtaining the embossment design layout scheme in the database and the corresponding chassis bearing strength when the same embossment design layout scheme is exist between the database and the second design table.
